(19) United States
(12) Patent Application Publication
(10) Pub. No.: US 2005/0242410 A1
(43) Pub. Date: Nov. 3, 2005

(54) Camera module, holder for use in a camera module, camera system and method of manufacturing a camera module

(75) Inventors: Erik Harold Groot, Eindhoven (NL); Anton Petrus Maria Van Arendonk, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/521,256

(22) PCT Filed: Jul. 11, 2003
(86) PCT No.: PCT/IB03/03131

§ 371 Date: Jan. 13, 2005

(30) Foreign Application Priority Data
Jul. 18, 2002 (EP) 02077932.8

(51) Int. Cl. H01L 31/0203

(52) U.S. Cl. 257/433

(57) ABSTRACT

The invention relates to a camera module 100. The camera module 100 comprises a holder 102, which provides a light-conducting channel 122. Within the light-conducting channel 122 a lens 120 having an optical axis 106 is present. A solid-state image sensor 113 is present near an end 128 of the light-conducting channel 122. The image sensor 113 is provided with an image section 114, which is oriented perpendicularly to the optical axis 106. Near the end 128 of the light-conducting channel, forming part of the holder 102, aligning means 131 are present for aligning the image section 114 with the optical axis 106. In one embodiment of the camera module 100, the inner wall 130 of the holder 102 is substantially rectangular, seen in cross-sectional view in a direction perpendicular to the optical axis 106. Bulges 131 present near the corners of the rectangle form the aligning means. The bulges 131 are provided with L-shaped recesses 129 in which the lateral surfaces 127 of the solid-state image sensor 113 are placed substantially without play. This method of aligning the image section 114 with the optical axis 106 simplifies the manufacture of the camera module 100.

The invention relates to a camera module comprising a holder provided with a light-conducting channel, within which channel a lens having an optical axis is present, a solid-state image sensor being present near an end of said light-conducting channel, which image sensor comprises an image section oriented perpendicularly to the optical axis.

The invention also relates to a holder provided with a light-conducting channel, which holder is intended for use in a camera module, which is arranged for accommodating a lens having an optical axis and which is furthermore arranged for placing a solid-state image sensor comprising an image section near an end of the light-conducting channel.

The invention also relates to a camera system comprising a camera module with a holder.

The invention furthermore relates to a method of manufacturing a camera module comprising a holder.

Such a camera module is known from European patent application EP-A 1 081 944. The known camera module is suitable for use in a camera system, such as a camera system incorporated in a telephone, in a portable computer or in a digital photo or video camera. With the known camera module, an image pickup module is placed into abutment with the second end of the holder. The image pickup module of the known camera module comprises a substrate. Present on the side of the substrate facing away from the holder, on which an electrically conductive wiring pattern has been formed, is a solid-state image sensor, for example a CCD (Charge Coupled Device) image sensor or a CMOS (Complementary Metal Oxide Semiconductor) image sensor. The solid-state image sensor is electrically connected to further electronics in a camera system of which the camera module forms part by means of electrically conductive connections, for example in the form of bumps of a suitably selected material, such as gold or another electrically conductive material. One side of the solid-state image sensor facing towards the substrate comprises a light-sensitive area arranged for converting incident light into electrical signals.

In one embodiment of the known camera module, the substrate consists of a non-transparent material, for example a metal plate covered with a flexible foil on which said wiring pattern is present, in which plate an aperture is present for transmitting light to the light-sensitive area of the solid-state image sensor. In another embodiment, the substrate consists of a light-transmitting material, such as glass, on which a conductive wiring pattern is present on the side facing towards the solid-state image sensor.

One drawback of the known camera module is the fact that it requires a complicated manufacturing method, which renders the camera module relatively costly.

It is an object of the invention to provide a camera module designed to enable simple manufacture. This object is achieved with a camera module according to the introductory paragraph, which is characterized in that aligning means forming part of the holder are present near the end of the light-conducting channel, which aligning means align the image section with respect to the optical axis.

In the camera module according to the invention, the position of the solid-state image sensor in the holder is fixed by the aligning means. Thus the position of the image section with respect to the optical axis is fixed as well. During manufacture it suffices, therefore, to place the solid-state image sensor in the holder, using the aligning means, in order to align the image section with respect to the optical axis. This results in a simplification of the manufacture of the camera module.

Furthermore it can be noted that the solid-state image sensor of the camera module according to the invention is not accommodated in an image pickup module, as is the case with the known camera module. Instead, the solid-state image sensor can be placed directly in the holder. This in itself already results in a simplification of the manufacture of the camera module. An additional result is that a reduction of the dimensions of the camera module is obtained, in particular in a direction parallel to the optical axis. This is an advantage, too, since the amount of available space is very limited in many applications in which the camera module is used, and in all probability it will be reduced even further in future applications.

One embodiment of the camera module according to the invention is characterized in that the image section extends in a plane parallel to a main surface of the solid-state image sensor, in which the solid-state image sensor comprises lateral surfaces oriented at least substantially perpendicularly to the main surface, and in which the light-conducting channel comprises an inner wall which is at least substantially polygonal near the end, seen in sectional view in a direction perpendicular to the optical axis, in which the aligning means comprise bulges present near the corners of the polygon, which bulges adjoin the inner wall and which abut against the lateral surfaces of the solid-state image sensor, as a result of which the solid-state image sensor is contained within the holder substantially without play in a direction perpendicular to the optical axis.

Since the bulges ensure that substantially no play remains between the inner wall of the holder and the lateral surfaces of the solid-state image sensor, the position of the solid-state image sensor and thus the position of the image section is fixed in a plane perpendicular to the optical axis of the lens. Thus it suffices to place the solid-state image sensor between the bulges, with the main surface extending perpendicularly to the optical axis and facing towards the lens, in order to align the image section with respect to the optical axis. This leads to a further simplification of the manufacture of the camera module as regards the alignment of the image section with respect to the optical axis.

Another embodiment of the camera module according to the invention is characterized in that the bulges are provided with an L-shaped recess, seen in cross-sectional view in a direction perpendicular to the optical axis, with one side of the bulge adjoining the inner wall at all times, whilst another side abuts substantially without play against two mutually adjacent lateral surfaces of the solid-state image sensor.

When the bulges are configured in this way, it will be easier to place the solid-state image sensor between bulges with the main surface extending perpendicularly to the optical axis and facing towards the lens. This leads to a further simplification of the manufacture of the camera module as regards the alignment of the image section with respect to the optical axis.

Another embodiment of the camera module according to the invention is characterized in that the substrate abuts against the supporting surface, which achieves that the image section is fixed in an orientation parallel to the optical axis.

After the solid-state image sensor has been bonded to the substrate, the main surface of the solid-state image sensor extends parallel to that side of the substrate on which the solid-state image sensor is present, since the main surface and the second main surface extend parallel to each other. As a result, the image section of the solid-state image sensor, too, extends parallel to that side of the substrate on which the solid-state image sensor is present. The supporting surface of the holder is oriented perpendicularly to the optical axis. This achieves that the image section is oriented perpendicularly to the optical axis after the holder has been placed on the substrate. This orientation leads to an improved quality of the images being projected onto the image section in use by the lens. This orientation is achieved in a simple manner as a result of the construction of the holder as described and the way in which it is attached to the substrate. This leads to a further simplification of the manufacture of the camera module.

A holder according to the invention for use in a camera module, which holder is provided with a light-conducting channel, which is arranged for accommodating a lens having an optical axis and which is furthermore arranged for placing a solid-state image sensor comprising an image section near an end of the light-conducting channel, is characterized in that aligning means forming part of the holder are present near said end of the light-conducting channel for aligning the image section with respect to the optical axis.

In the holder according to the invention, the position at which the solid-state image sensor comprising the image section is to be placed is fixed by the aligning means. Thus, the position of the image section with respect to the optical axis is fixed as well. Upon manufacture of the camera module it thus suffices to place the solid-state image sensor in the holder, using the aligning means, in order to align the image section with respect to the optical axis. Consequently, the manufacture of the camera module is simplified by using the holder according to the invention when manufacturing the camera module.

A camera system according to the invention comprises a camera module comprising a holder provided with a light-conducting channel in which a lens having an optical axis is present, in which a solid-state image sensor provided with an image section oriented perpendicularly to the optical axis is present near an end of the light-conducting channel, and in which aligning means forming part of the holder are present near said end of the light-conducting channel for aligning the image section with respect to the optical axis.

The camera system according to the invention employs a camera module in which the position of the solid-state image sensor in the holder is fixed by the aligning means. Thus, the position of the image section with respect to the optical axis is fixed as well. During manufacture it suffices, therefore, to place the solid-state image sensor in the holder, using the aligning means, in order to align the image section with respect to the optical axis. This results in a simplification of the manufacture of the camera system.

A method of manufacturing a camera module comprising a holder is characterized in that the holder is provided with aligning means, in which the solid-state image sensor comes into contact with the aligning means upon placement of the solid-state image sensor in said holder, as a result of which an image section present on the solid-state image sensor is aligned with respect to an optical axis.

During manufacture, a lens having an optical axis is placed in the holder. For a correct operation of the camera module it is important that the solid-state image sensor is aligned with respect to the optical axis in a plane perpendicular to the optical axis. In order to achieve this, the camera module is provided with aligning means upon manufacture. Automatic alignment of the image section with respect to the optical axis is achieved by placing the solid-state image sensor into contact with the aligning means upon placement of the solid-state image sensor in the holder. This results in a simplification of the manufacture of the camera system.

These and other aspects of the invention will now be discussed in more detail with reference to the drawings, in which:

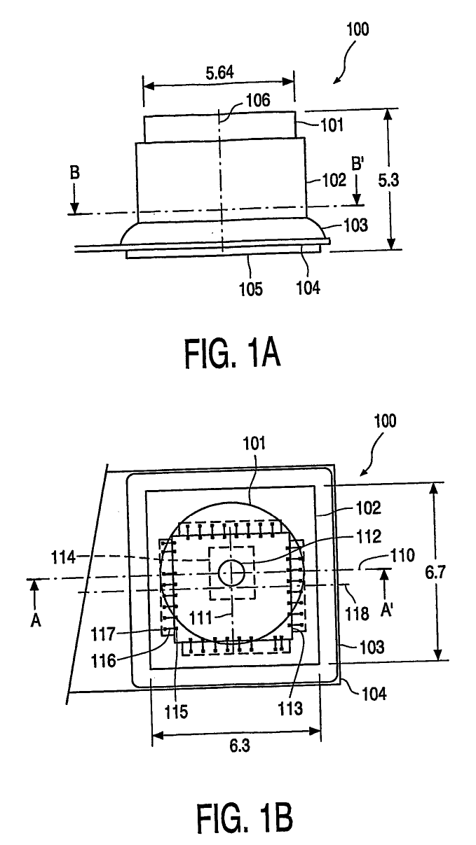

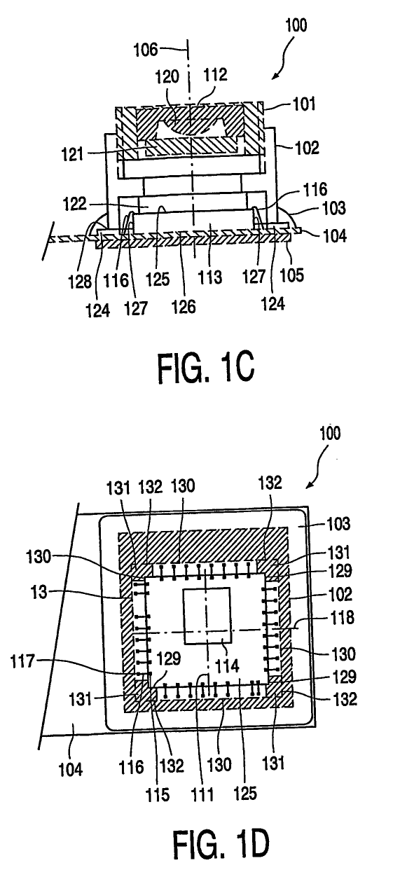

FIGS. 1A-D schematically show an embodiment of the camera module according to the invention;

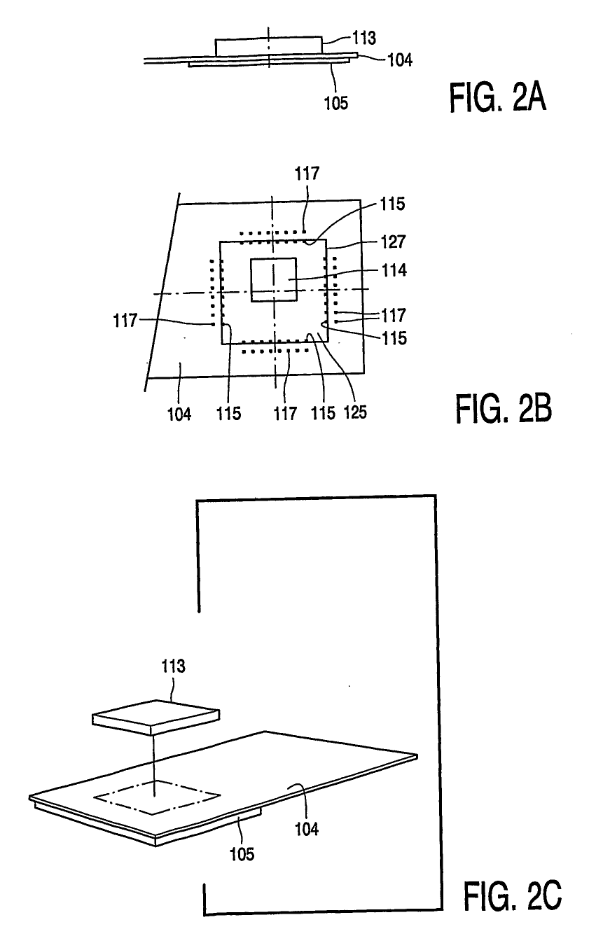

FIGS. 2A-C schematically show a manufacturing step of the camera module according to the invention;

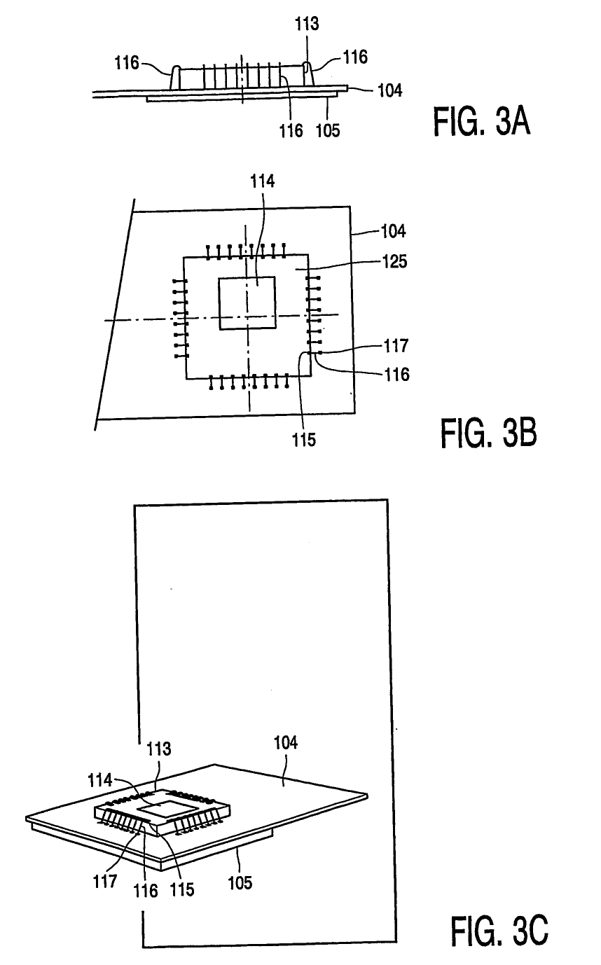

FIGS. 3A-C schematically show a further manufacturing step of the camera module according to the invention;

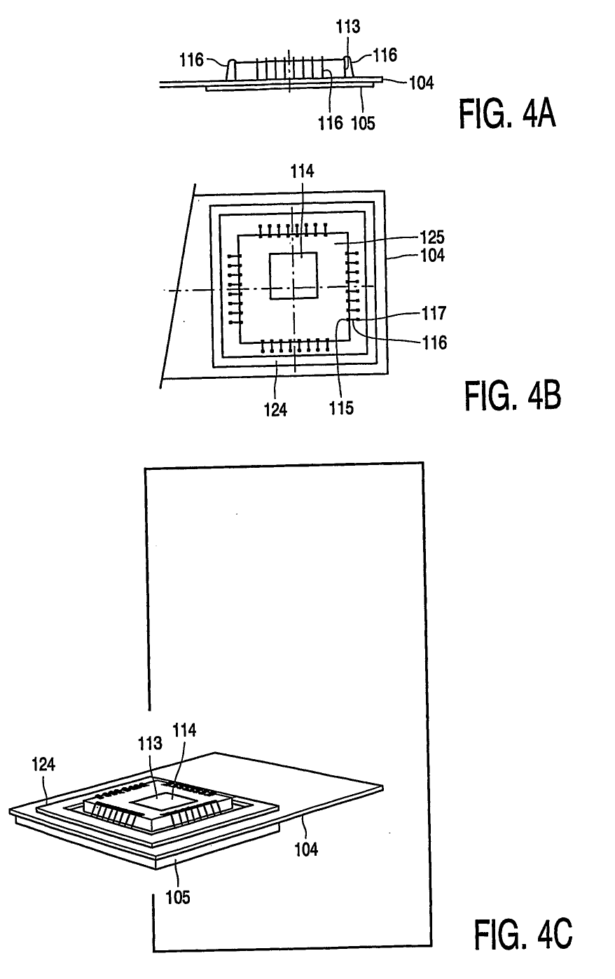

FIGS. 4A-C schematically show a further manufacturing step of the camera module according to the invention;

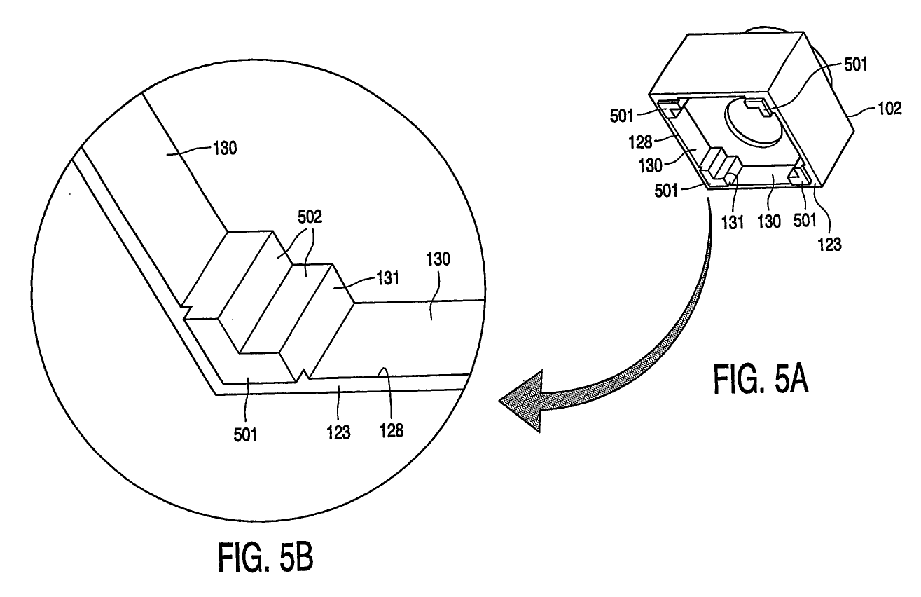

FIGS. 5A-B schematically show in perspective view of the holder of the camera module;

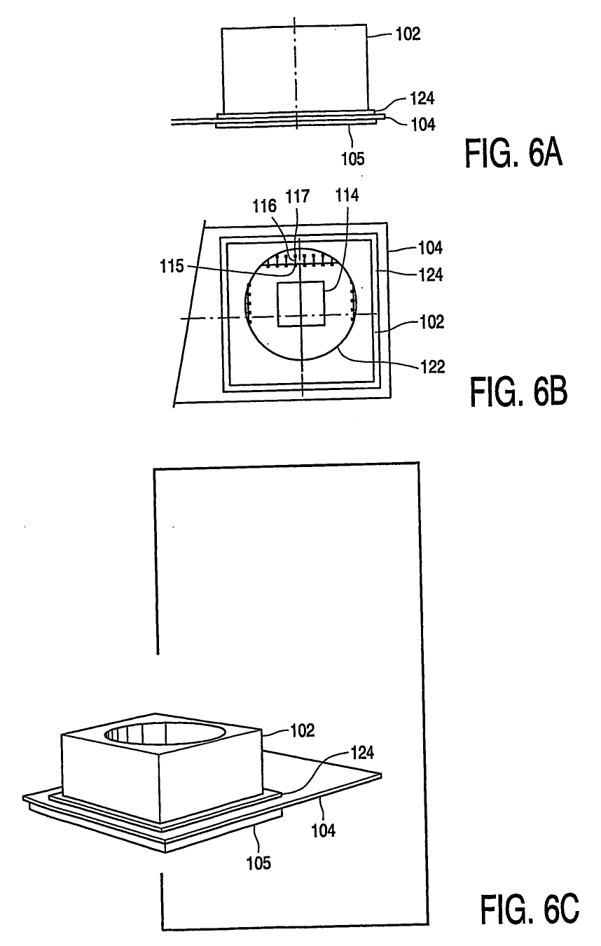

FIGS. 6A-C schematically show a further manufacturing step of the camera module according to the invention;

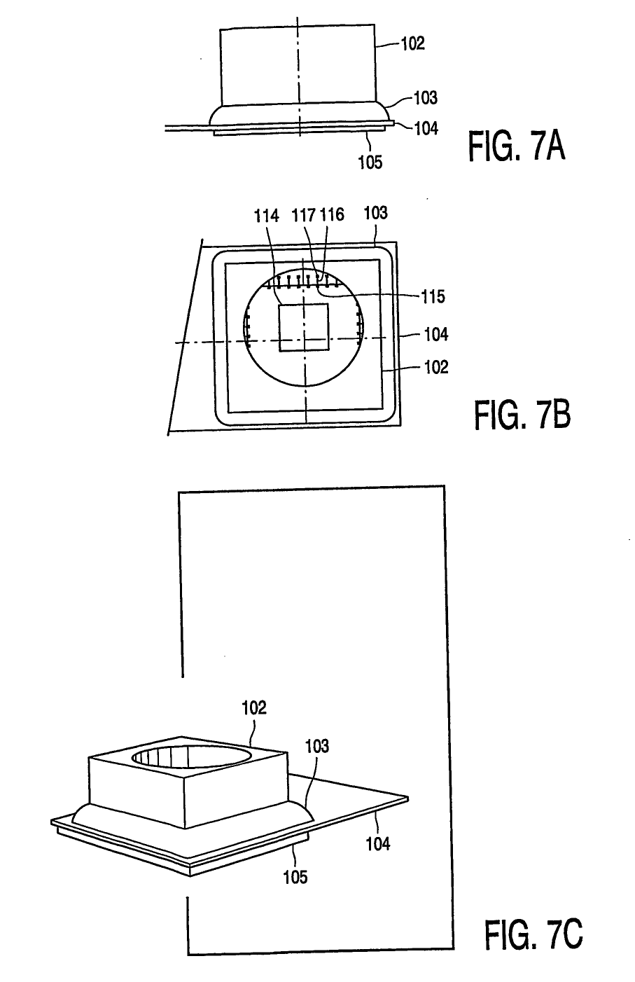

FIGS. 7A-C schematically show a further manufacturing step of the camera module according to the invention;

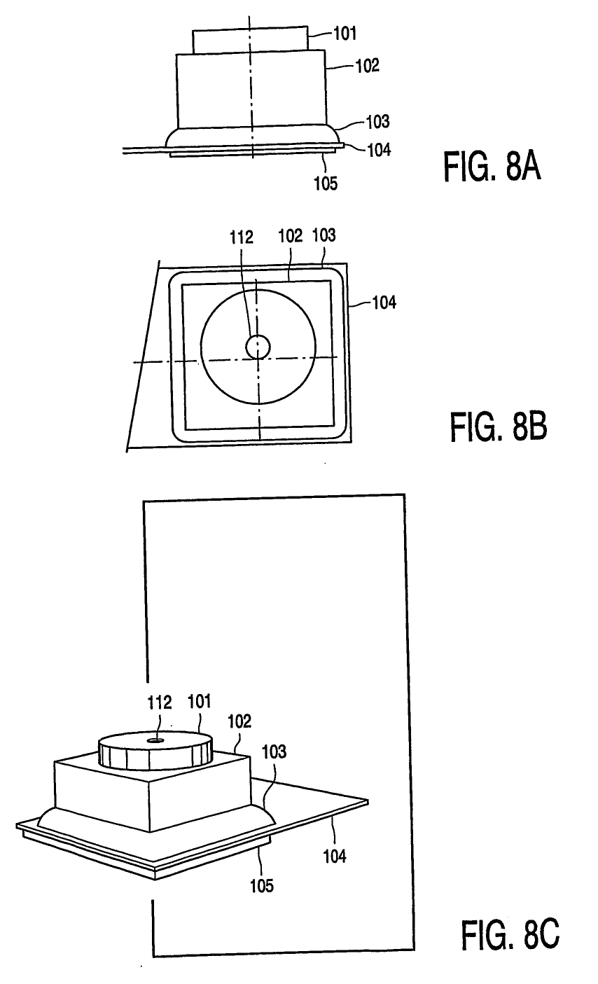

FIGS. 8A-C schematically show a further manufacturing step of the camera module according to the invention; and

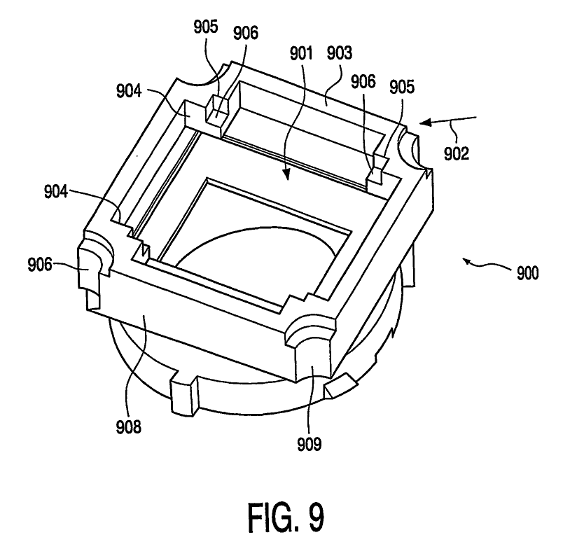

FIG. 9 schematically shows in perspective view a second embodiment of a holder for a camera module according to the invention.

In the figures, like parts are indicated by the same numerals.

FIGS. 1A-D schematically show an embodiment of the camera module according to the invention. FIG. 1A is a side elevation of a camera module 100 according to the invention. The camera module comprises a barrel 101 which is mounted in a holder 102, a substrate 104 of a flexible material (a flex foil), on which the holder 102 is present, a seal 103 consisting of glob top material for sealing the joint between the holder 102 and the substrate 104, and a stiffener 105 for stiffening the substrate. The optical axis of the camera module is illustrated in the broken line 106. A usual height of the camera module, measured from the barrel 101 to the stiffener 105, is about 5.0-5.5 mm, for example. A usual diameter of the barrel is about 5.5-6.0 mm, for example.

FIG. 1B shows the camera module 100 in top plan view. The figure shows the substrate 104 with the glob top material 103 present thereon, as well as the holder 102 and the barrel 101, respectively. The optical axis 106 is represented by the point of intersection of the lines 110 and 111. In addition to that, the holder 102 has a central axis. After assembly of the camera module, said central axis extends parallel to the optical axis 106. In FIG. 1B said central axis is represented by the point of intersection of the lines 111 and 118. A usual width of the holder is about 6.0-6.5 mm. for example. A usual length of the holder is about 6.5-7.0 mm, for example. FIG. 1B also shows a lens aperture 112 in the barrel 101 for transmitting light. Furthermore, FIG. 1B shows a solid-state image sensor 113 with an image section 114 present thereon. The solid-state image sensor 113 is provided with bond pads 115, which electrically connect the integrated electronic circuits on the solid-state image sensor 113 to pads 117 on the substrate via bonding wires 116. The pads 117 can be connected to other electronic circuits and to a power supply, for example a battery or the output of a mains adapter, in a camera system by means of a pattern of conductive tracks. In this way the solid-state image sensor 113 can be supplied with the required electric voltages, and electrical signals, which are generated by the incident light in the image section 114, for example, can be transmitted to the other electronic circuits in the camera system.

FIG. 1C is a longitudinal sectional view of the camera module 100 along the plane AA′ in FIG. 1B, which is oriented parallel to the optical axis 106. The figure shows the barrel 101 containing a lens 120 and an infrared filter 121, with the lens aperture 112 being present at the upper side. The barrel 101 is mounted in the holder 102. Inside the holder 102 is a light-conducting channel 122 having an end 128. A bonding area 123 is present at the end 128 of the light-conducting channel 122. Disposed between the bonding area 123 and the substrate 104 is an adhesive material 124, for example a suitably selected glue, by means of which the holder 102 is attached to the substrate 104. Present on the outer side of the holder 102, near the point of attachment of the holder 102 to the substrate, is the glob top material 103, which fully covers the adhesive material 124. Thus the connection between the holder 102 and the substrate 104 is strengthened and protected. The solid-state image sensor 113 comprises a main surface 125, which faces towards the lens 120, and a second main surface 126, which is attached to the substrate 104 in a usual manner. The main surface 125 and the second main surface 126 are oriented perpendicularly to the optical axis 106. FIG. 1C furthermore shows the lateral surfaces 127 of the solid-state image sensor 113. Said surfaces abut the main surface 125 and the second main surface 126, being oriented perpendicularly thereto. Finally, FIG. 1C also shows the bonding wires 116, which electrically connect the bond pads 115 that are shown in FIG. 1B to the pads 117.

FIG. 1D is a cross-sectional view of the camera module 100 along the plane BB′ in FIG. 1A, which plane is oriented perpendicularly to the optical axis 106. The figure shows the holder 102 and an inner wall 130 in cross-sectional view. The inner wall 130 is rectangular along the plane BB′. Disposed within this said rectangle is the solid-state image sensor 113, whose main surface 125 and the image section 114 present within the confines thereof is shown in top plan view. The main surface 125 is likewise rectangular, and it is enclosed by the inner wall 130. Bulges 131 are present near the comers of the rectangle formed by the cross-section of the inner wall.

On the one hand, the bulges 131 comprise an L-shaped recess 129, and on the other hand they abut the inner wall 102 in the comers. As a result, the bulges 131 are likewise L-shaped, seen in the cross-sectional view of FIG. 1D. The recesses 129 in the bulges 131 abut the lateral surfaces 127 of the solid-state image sensor 113 substantially without play. This achieves that the image section 114 is aligned with respect to the optical axis 106. In FIG. 1D, the bulges 131 are separated from the holder 102 by a broken line 132 for the sake of clarity. In actual fact the bulges 131 will usually be integral with the holder 102, since this simplifies the manufacture of the whole.

Within the holder 102, space has been left for the pads 117 and the bonding wires 116 between the inner wall 130 and the lateral surfaces 127 of the solid-state image sensor, so that said pads and said bonding wires are entirely confined within the holder 102. The practical advantage of this configuration is that the bonding wires 116, which are mechanically fairly vulnerable, are screened in this way. In addition to the elements that have already been mentioned, FIG. 1D also shows the substrate 104 and the glob top material 103 that strengthens and protects the connection between the holder 102 and the substrate 104.

A camera system in which the camera module 100 is used has this advantage that it can be small, since the dimensions of the camera module 100 are small in comparison with those of known camera modules. Another advantage of a camera system in which the camera module 100 is used is that it is cheaper to produce, since the camera module 100 is simpler and can thus be produced at lower cost than known camera modules.

FIGS. 2A-C schematically show a manufacturing step of the camera module according to the invention. FIG. 2A is a side elevation, in which the solid-state image sensor 113 is present on the substrate 104, with the stiffener 105 being present on the other side of the substrate 104. FIG. 2B is a top plan view of the solid-state image sensor 113 that is present on the substrate 104. Disposed within the confines of the main surface 125 of the solid-state image sensor 113 is the image section 114, as are the bond pads 115 being arranged in rows near the lateral surfaces 127 and extending parallel thereto. Present on the side of the substrate 104 to which the solid-state image sensor 113 is attached are also the pads 117. Said plans extend parallel to the lateral surfaces 127. FIG. 2C schematically shows in perspective view the placing of the solid-state image sensor 113 on the substrate 104.

It is common practice to test the functionality of the solid-state image sensor 113 before starting the assembly of the camera module 100. Normally, this takes place while the solid-state image sensor 113 is still present on a wafer. After such a functional test has been carried out, the wafer is diced. The solid-state image sensors 113 that have passed the functional test are subsequently used in the manufacture of the camera module 100. This prevents non-functioning solid-state image sensors 113 being used upon manufacture of camera modules.

An adhesive is applied to the flex foil substrate 104 before the solid-state image sensor 113 is bonded to the substrate 104. Said adhesive may be a usual glue or a PSA foil. Subsequently, the solid-state image sensor 113 is placed on the substrate by means of a pick and place machine, and the second main surface 126 is placed into contact with the substrate. Following this, the adhesive is cured.

FIGS. 3A-C schematically show a manufacturing step of the camera module according to the invention. FIG. 3A is a side elevation which shows, in addition to the elements that are shown in FIG. 2A, the bonding wires 116 that connect the bond pads 115 (not shown) to the pads 117 (likewise not shown) on the substrate 104. FIG. 3B is a top plan view which shows, in addition to the elements that are shown in FIG. 2B, the bonding wires 116 that connect the bond pads 115 to the pads 116 on the substrate. FIG. 3C is a schematic, perspective view of the solid-state image sensor 113 provided with the image section 114, which is present on the substrate 104, in which the bond pads 115 of the solid-state image sensor 113 are connected to the pads 117 on the substrate by means of the bonding wires 116.

After curing of the adhesive by means of which the solid-state image sensor 113 is attached to the substrate 104, the bonding wires 116 that electrically connect the bond pads 115 to the pads 117 are provided. It may be advantageous in that connection if the stiffener 105 is present. As a result of the presence of said stiffener, the assembly consisting of the solid-state image sensor 113 and the substrate is easier to handle during the wire bonding process, i.e. the provision of the bonding wires. Said wire bonding may take place in a known manner. Electrical connections between integrated circuits on a solid-state image sensor and electrical connections on a substrate may also be effected in a different manner, for example by means of stud bumps. One drawback of the use of stud bumps, however, is the fact that they require larger pads on the solid-state image sensor 113.

FIGS. 4A-C schematically show a further manufacturing step of the camera module according to the invention. FIG. 4A is a side elevation, which shows the same elements as in FIG. 3A. FIG. 4B is a top plan view which shows, in addition to the elements that are present in FIG. 3B, the adhesive material 124 after it has been applied to the substrate 104. The adhesive material forms an at least substantially rectangular pattern on the substrate 104 along the circumference of the solid-state image sensor 113 that is present on the substrate 104. The form and the dimensions of the pattern in which the adhesive material has been applied are at least substantially identical to the form and the dimensions of the end of the light-conducting channel of the holder 102. FIG. 4C is a perspective view which shows, in addition to the elements that are shown in FIG. 3C, the adhesive material 124 after it has been applied to the substrate 104.

The adhesive material 124, which may be a glue which is commonly used for this purpose, has been applied in a pattern in which space has been left between the solid-state image sensor 113 and the adhesive material 124. It is in particular important that space be left on the substrate 104 in the direct vicinity of the corners of the solid-state image sensor 113. If adhesive material 124 would actually be present at these locations, this might result in a tilt of the image section 114 with respect to the optical axis 106. In other words, the image section 114 would not be positioned in a plane oriented perpendicularly to the optical axis 106. This leads to a decreased quality of the image that is formed on the image section 114 by the lens 120 in use.

FIGS. 5A-B schematically show the holder 102 of the camera module 100 in perspective view. FIG. 5A is a schematic, perspective view of the holder 102, seen from the side that is placed into abutment with the substrate 104. The figure shows the bulges 131 that are present in the inner wall 130 of the holder 102, near the comers of the light-conducting channel 122. The bulges 131 are provided with an L-shaped recess 502, seen in sectional view in a direction perpendicular to the central axis, so that the bulges 131 are likewise L-shaped, seen in the same sectional view. Once the assembly of the camera module is complete, the central axis of the holder 102 extends parallel to the optical axis 106, as is shown in FIG. 1B. FIG. 5A also shows the bonding area 123 to be present at the end 128 of the light-conducting channel 122, which surface is oriented perpendicularly to the central axis of the holder 102.

FIG. 5B is an enlarged view of one of the bulges 131 and an adjoining part of the inner wall 130 of the holder 102 and the bonding area 123. FIG. 5B furthermore shows more clearly that the bulges 131 partially extend outside the light-conducting channel 122. Each of the bulges 131 has a second end 501, which extends in a plane perpendicular to the central axis of the holder 102. Said second ends jointly form a supporting surface, which is oriented perpendicularly to the central axis of the holder 102.

After the adhesive material 124 has been applied to the substrate 104, the holder 102 is placed over the solid-state image sensor 113 on the substrate 104. On the other hand, it may be advantageous to arrange the assembly comprising the solid-state image sensor 113 and the substrate 104 inside the holder 102. This may depend on the production circumstances. In both cases the second ends 501 of the bulges 131 make contact with the substrate 104, as a result of which the solid-state image sensor is oriented perpendicularly to the central axis of the holder 102 and consequently also perpendicularly to the optical axis 106 of the lens 120 that is yet to be placed. The L-shaped recesses 502 of the bulges 131 come into contact with the lateral surfaces 127 of the solid-state image sensor 113, as a result of which the position of the image section 114 of the solid-state image sensor with respect to the central axis of the holder 102 is fixed. By this, the image section 114 is also aligned with respect to the optical axis 102 of the lens 120, if said lens is present. The bonding area 123 is placed into contact with the adhesive material 124, by which the position of the holder 102 with respect to the substrate 104 is fixed.

The adhesive material 124 also functions to seal the interior part of the holder 102 in which the solid-state image sensor 113 is now present. Another advantage of the holder 102 and of the way of attachment to the substrate thereof is that the adhesive material 124 and the glob top material 103 (yet to be provided) remain separated from the image section 113 by a relatively large distance, so that the latter will not become soiled with adhesive material or glob top material.

FIGS. 6A-C schematically show a further manufacturing step of the camera module according to the invention. FIG. 6A is a side elevation of the holder 102, which is attached to the substrate 104 by means of the adhesive material 124, with the stiffener 105 being present on the other side of the substrate. FIG. 6B is a top plan view of the holder 102 attached to the substrate 104 by means of the adhesive material 124. The adhesive material 124 partially extends outside the holder 102. This simplifies the application of the adhesive material to the substrate 104 in a previous step, since a proper bond remains ensured, also if the application of the adhesive material takes place relatively inaccurately. Furthermore, part of the solid-state image sensor 113 and the image section 114 present thereon can be seen via the light-conducting channel 122.

FIG. 6C shows in perspective view the holder 102, which is attached to the substrate 104 via the adhesive material 124, with the stiffener 105 being present on the other side of the substrate 104.

FIGS. 7A-C schematically show a further manufacturing step of the camera module according to the invention. FIG. 7A is a side elevation which shows, in addition to the elements that are shown in FIG. 6A, the glob top material 103 which abuts both the outer side of the holder 102 and the substrate 104, and which screens and strengthens the connection between the two formed by the adhesive material 124. FIG. 7B is a top plan view which shows, in addition to the elements that are shown in FIG. 6A, the glob top material 103. FIG. 7C is a perspective view which shows, in addition to the elements that are shown in FIGS. 6C, the glob top material 103.

The viscosity of the glob top material 103 being used must not be too low upon application thereof, since otherwise the material will not remain in contact with the outer side of the holder 102 to a sufficient degree. The provision of the glob top material may be omitted under certain circumstances, if the adhesive material 124 itself provides a sufficient seal and a sufficiently strong connection between the holder 102 and the substrate 104. It is also possible not to apply the glob top material 103 until the barrel 101 containing the lens 120 has been placed in the holder 102. Since the glob top material 103 must generally be cured at a relatively high temperature, however, this means that the material of the lens 120 must be capable of withstanding said high temperature.

FIGS. 8A-C schematically show a further manufacturing step of the camera module according to the invention. FIG. 8A is a side elevation which shows, in addition to the elements that are shown in FIG. 7A, the barrel 101 containing the lens 120, which is mounted in the holder 102. FIG. 8B is a top plan view which shows, in addition to the elements that are present in FIG. 7B, the barrel 101 mounted in the holder 102, which barrel contains the lens 120, which is disposed behind the lens aperture 112. FIG. 8C is a perspective view which shows, in addition to the elements that are shown in FIG. 7C, the barrel 101 mounted in the holder 102, which barrel contains the lens 120, which is disposed behind the lens aperture 112.

The barrel 101 has an outer side which is cylindrical in shape, with the axis of the cylinder coinciding with the optical axis 106 of the lens 120. The part of the holder 102 in which the barrel 101 is mounted has a cylindrical inner side whose central axis extends parallel to the central axis of the holders 102, which inner side corresponds to the outer side of the barrel. The outer side of the barrel 101 and the inner side of the holder 102 may be smooth, so that the barrel is slid into the holder 102 upon assembly. The outer side of the barrel 101 and the inner side of the holder 102 may also be provided with two mating screw threads, in which case the barrel 101 is screwed into the holder 102 upon assembly. In both cases the lens 101 is focused with respect to the image section 114 of the solid-state image sensor 113, after which the barrel 101 is fixed in position with respect to the holder 102 in a usual manner, for example by means of suitably selected glue, or by means of laser welding or an ultrasonic welding technique.

FIG. 9 is a perspective view of a second embodiment of a holder for a camera module according to the invention. The holder 900 is provided with a light-conducting channel 901 having a central axis which, after mounting of a barrel containing a lens, for example the barrel 101 containing the lens 120 that is shown in FIGS. 1A-D, extends parallel to the optical axis of the lens. The end of the light-conducting channel 901, which is indicated by the arrow 902, comprises a bonding area 903, via which the holder 900 can be attached to a substrate. Near the end 902, the light-conducting channel 901 is substantially rectangular, seen in sectional view in a direction perpendicular to the central axis, with bulges provided with L-shaped recesses 905 being present in the comers. After assembly of a camera module, the L-shaped recesses abut the lateral surfaces of a solid-state image sensor, for example the solid-state image sensor 113 that is shown in FIGS. 1A-D, substantially without play.

The L-shaped recesses 905 do not continue over the entire bulge 904, but they each terminate on an end surface 906 extending in a direction perpendicular to the central axis of the light-conducting channel 901. The end surfaces 906 jointly form an abutting surface perpendicular to the central axis of the light-conducting 901. After assembly of the camera module, said abutting surface abuts against the main surface of the solid-state image sensor, for example the main surface 125 of the solid-state image sensor 113. In this way it is ensured that an image section of the solid-state image sensor, for example the image section 114 of the solid-state image sensor 113, is oriented perpendicularly with respect to the optical axis. This has a positive effect on the quality of the image being projected onto the image section by the lens.

The holder 900 furthermore has an outer wall 908, which is rectangular, seen in sectional view in a direction perpendicular to the central axis, and recesses 909 in the form of a segment of a cylinder extending in a direction parallel to the central axis are present in the comers. One advantage of these recesses is the fact that they make it easier to handle the holder upon manufacture of the camera module. Finally, the holder 900 may be provided with an infrared filter extending in a direction perpendicular to the central axis of the light-conducting channel.

It will be understood that the invention is not limited to the examples that are given herein, but that a great many additional variants are possible within the scope of the invention. Thus, the order in which the various elements of the camera module 100 are assembled may be adapted as the production circumstances require. Furthermore it will be understood that whilst a barrel containing one lens is shown in the embodiments that are shown herein, it is possible to substitute said lens for a system of lenses. It will also be understood that the substrate 104 does not necessarily have to be a flexible foil, but that it is also possible to use a usual PCB printed circuit board) material for this purpose. One advantage of the use of a PCB substrate is the fact that it makes it easier to test the camera module, since it is relatively easy to attach test pads thereto. This may be done on an unused portion on the side of the substrate to which the holder 102 is attached. It is also possible in many cases to attach the test pads to the substrate on the other side thereof. Furthermore it will be apparent to those skilled in the art that it is possible to use a solid-state image sensor that is sensitive to electromagnetic radiation other than visible light instead of the solid-state image sensor that is sensitive to light.

Summarizing the above, the invention relates to a camera module 100. The camera module 100 comprises a holder 102, which is provided with a light-conducting channel 122. Present in said light-conducting channel 122 is a lens 120 having an optical axis 106. Disposed near an end 128 of the light-conducting channel 122 is a solid-state image sensor 113, which is provided with an image section 114 that is oriented perpendicularly to the optical axis 106. Aligning means 131 forming part of the holder 102 are present near the end 128 of the light-conducting channel 122. Said aligning means align the image sensor 114 with respect to the optical axis 106. In one embodiment of the camera module 100, the inner wall of the holder 102 is substantially rectangular near the end 128, seen in sectional view in a direction perpendicular to the axis, and the aligning means are formed by bulges 131 that are disposed near the comers of the rectangle. The bulges 131 are provided with an L-shaped recess, which abuts the lateral surfaces 127 of the solid-state image sensor 113 substantially without play. This manner of aligning the image section 114 with respect to the optical axis simplifies the manufacture of the camera module 100.

1. A camera module comprising a holder provided with a light-conducting channel, within which channel a lens having an optical axis is present, a solid-state image sensor being present near an end of said light-conducting channel, which image sensor comprises an image section oriented perpendicularly to the optical axis, characterized in that aligning means forming part of the holder are present near the end of the light-conducting channel, which aligning means align the image section with respect to the optical axis.

2. A camera module as claimed in claim 1, characterized in that the image section extends in a plane parallel to a main surface of the solid-state image sensor, in which the solid-state image sensor comprises lateral surfaces oriented at least substantially perpendicularly to the main surface, and in which the light-conducting channel comprises an inner wall which is at least substantially polygonal near the end, seen in sectional view in a direction perpendicular to the optical axis, in which the aligning means comprise bulges present near the corners of the polygon, which bulges adjoin the inner wall and which abut against the lateral surfaces of the solid-state image sensor, as a result of which the solid-state image sensor is contained within the holder substantially without play in a direction perpendicular to the optical axis.

3. A camera module as claimed in claim 2, characterized in that said polygon is a rectangle.

4. A camera module according to claim 2, characterized in that said bulges are provided with an L-shaped recess, seen in cross-sectional view in a direction perpendicular to the optical axis, with one side of the bulge adjoining the inner wall at all times, whilst another side abuts substantially without play against two mutually adjacent lateral surfaces of the solid-state image sensor.

5. A camera module as claimed in claim 2, characterized in that the end of the light-conducting channel forms a bonding area extending perpendicularly to the optical axis.

6. A camera module as claimed in claim 2, characterized in that said bulges partially extend outside the light-conducting channel, each bulge having a second end, which ends jointly form a supporting surface which is oriented perpendicularly to the optical axis.

7. A camera module as claimed in claim 5, characterized in that the camera module comprises a substrate, in which the solid-state image sensor comprises a second main surface bonded to the substrate, in which the substrate is bonded to the bonding area by means of an adhesive material.

8. A camera module as claimed in claim 7, characterized in that the substrate abuts against the supporting surface, which achieves that the image section is fixed in an orientation parallel to the optical axis.

9. A holder for use in a camera module, which holder is provided with a light-conducting channel, which is arranged for accommodating a lens having an optical axis and which is furthermore arranged for placing a solid-state image sensor comprising an image section near an end of the light-conducting channel, characterized in that aligning means forming part of the holder are present near said end of the light-conducting channel for aligning the image section with respect to the optical axis.

10. A holder as claimed in claim 9, characterized in that the holder comprises an outer wall which is at least substantially polygonal, seen in sectional view in a direction perpendicular to the optical axis, in which recesses are present in the outer wall near the corners, which recesses extend in a direction parallel to the optical axis.

11. A camera system comprising a camera module with a holder provided with a light-conducting channel in which a lens having an optical axis is present, in which a solid-state image sensor provided with an image section oriented perpendicularly to the optical axis is present near an end of the light-conducting channel, and in which aligning means forming part of the holder are present near said end of the light-conducting channel for aligning the image section with respect to the optical axis.

12. A method of manufacturing a camera module comprising a holder, characterized in that the holder is provided with aligning means, in which the solid-state image sensor comes into contact with the aligning means upon placement of the solid-state image sensor in said holder, as a result of which an image section present on the solid-state image sensor is aligned with respect to an optical axis.
